(19) United States
(12) Patent Application Publication
(10) Pub. No.: US 2013/0215627 A1
(43) Pub. Date: Aug. 22, 2013

(54) ELECTRONIC UNIT BASE AND ELECTRONIC MODULE AND ELECTRONIC DEVICE USING THE SAME

(71) Applicant: Lextar Electronics Corporation, (US)

(72) Inventor: Chia-En LEE, Chiayi City (TW)

(73) Assignee: Lextar Electronics Corporation, Hsinchu (TW)

(21) Appl. No.: 13/712,475

(22) Filed: Dec. 12, 2012

(30) Foreign Application Priority Data
Feb. 21, 2012 (TW) 101105597

(51) Int. Cl. H05K 1/02; H05K 7/02; H05K 1/11; F21V 21/00

(52) U.S. Cl. CPC H05K 1/02; F21V 21/00; H05K 7/02; H05K 1/11
USPC 362/382; 361/728; 174/250; 174/261

(57) ABSTRACT

The electronic unit base includes a body and a first conducting layer. The body includes a supporting face, a bottom face, and a first incline. The supporting face and the bottom face are disposed on the opposite sides of the body. The first incline is disposed on one side of the body between the supporting face and the bottom face, wherein the first incline and the bottom face substantially have a first angle. The first conducting layer is disposed on the supporting face and extends toward the first incline, wherein the first conducting layer covers a portion of the supporting face and a portion of the first incline.

### BACKGROUND

1. Technology Field

This disclosure generally relates to an electronic unit base, and an electronic unit module and an electronic device using the same. More particularly, this disclosure relates to a light-emitting diode (LED) base, and a LED module and a LED device using the same.

2. Description of the Prior Art

The use of LED in various electronic products and industries is very popular. The energy cost of LED is much less than conventional incandescent lamp or fluorescent lamp, and the size of a single LED is relatively much smaller. The above features make LEDs superior to conventional light sources. With a trend of minimizing the size of electronic device, the demand of LED is increasing.

While in use, two electrodes of a LED must be coupled to circuits. More particularly, as shown in FIG. 1A, a conventional LED device 60 has a LED unit 50 disposed on a base 10, wherein electrodes 51 and 52 of the LED unit 50 are respectively coupled to electrodes 31 and 32 of the base 10, and then the electrodes 31 and 32 are respectively coupled to electrodes 71 and 72 on the circuit board by wire 91. In such a design, the wire 91 easily breaks off when the LED is used in high power or is manufactured in high temperature. On the other hand, as another LED device 60 shown in FIG. 1B, holes 11 is formed through the base 10 from the top face to the bottom face of the base 10, wherein holes 11 are filled with a conducting material to respectively couple the electrodes 31 and 32 of the base 10 with the electrodes 71 and 72 on the circuit board 70. In such a design, the formation of holes 11 is complicated and costly. Thus, the conventional LED device is still improvable.

### SUMMARY

It is an object of the present invention to provide an electronic unit base having lower packaging cost.

It is another object of the present invention to provide an electronic unit module having lower packaging cost.

It is still another object of the present invention to provide an electronic device having lower packaging cost.

The electronic unit base includes a body and a first conducting layer. The body includes a supporting face, a bottom face, and a first incline. The supporting face and the bottom face are disposed on opposite sides of the body. The first incline is disposed on one side of the body between the supporting face and the bottom face, wherein the first incline and the bottom face substantially have a first angle. The first conducting layer is disposed on the supporting face and extends toward the first incline, wherein the first conducting layer covers a portion of the supporting face and a portion of the first incline.

The electronic unit base further includes a first side face disposed between the first incline and the bottom face. The height of the first side face is less than 1 mm. The electronic unit base further includes a second incline and a second conducting layer. The second incline is disposed on the other side of the body between the supporting face and the bottom face, wherein the second incline and the bottom face substantially have a second angle. The second conducting layer is disposed on the supporting face and extending toward the second incline, wherein the second conducting layer covers a portion of the supporting face and a portion of the second incline, wherein the second conducting layer and the first conducting layer are physically separated.

The first incline and the second incline are respectively disposed on the opposite sides of the body and between the supporting face and the bottom face. The electronic unit base further includes a second side face disposed between the second incline and the bottom face. The height of the second side face is less than 1 mm.

The electronic unit base further includes a second conducting layer disposed on the supporting face and extending toward the first incline, wherein the second conducting layer covers a portion of the supporting face and a portion of the first incline. The second conducting layer and the first conducting layer are physically separated.

The electronic unit module of the present invention includes the above electronic unit base and an electronic unit. The electronic unit has a first electrode and a second electrode respectively coupled to the first conducting layer and the second conducting layer coving the supporting face. The electronic unit is a LED. The first electrode and the second electrode are disposed on the same side of the electronic unit, wherein the first electrode and the second electrode are respectively coupled to the first conducting layer and the second conducting layer by Flip-Chip bonding of the electronic unit. The first electrode and the second electrode are disposed on the opposite sides of the electronic unit, wherein the first electrode covers and is coupled with the first conducting layer, wherein the second electrode is coupled to the second conducting layer by a wire.

The electronic device of the present invention includes the above electronic unit module and a substrate. The substrate has a first substrate electrode and a second substrate electrode respectively coupled to the first conducting layer and the second conducting layer. The first substrate electrode and the second substrate electrode are respectively coupled to the first conducting layer and the second conducting layer by conducting paste. The first substrate electrode and the second substrate electrode respectively have a first reed and a second reed, wherein the first substrate electrode and the second substrate electrode are respectively coupled to the first conducting layer and the second conducting layer by using the first reed and the second reed. The electronic unit module is embedded into the substrate, wherein the bottom face is sunk into the substrate. The electronic unit module is embedded into the substrate, wherein at least a portion of the first side face is sunk into the substrate.

The electronic unit base further includes at least one conducting electrode disposed on the supporting face. The electronic unit module includes an electronic unit base and a plurality of electronic units. Each electronic unit has a first electrode and a second electrode, wherein the first electrode of one of the plurality of electronic units is coupled to the first conducting layer covering the supporting face and the second electrode of another of the plurality of electronic units is coupled to the second conducting layer covering the supporting face, wherein the plurality of electronic units are coupled to each other in series by the at least one conducting electrode. The electrode device includes the above electronic unit module and a substrate having a first substrate electrode and a second substrate electrode respectively coupled to the first conducting layer and the second conducting layer.

### BRIEF DESCRIPTION OF THE DRAWINGS

FIGS. 1A and 1B are schematic views of the prior art;

FIG. 2A is a schematic view of the preferred embodiment of the electronic unit base of the present invention;

FIG. 2B is a schematic view of the preferred embodiment of the electronic unit module of the present invention;

FIG. 2C is a schematic view of the preferred embodiment of the electronic device of the present invention;

FIG. 3 is a schematic view of an embodiment of the present invention showing the first electrode and the second electrode disposed on opposite sides of the electronic device;

FIG. 4 is a schematic view of an embodiment of the present invention showing the conducting layer coupled to the electrodes of the substrate by reeds;

FIGS. 5-7 are schematic views of embodiments of the present invention showing the electronic unit module embedded into the substrate;

FIG. 8 is a top view of an embodiment of the electronic unit base of the present invention;

FIG. 9 is a top view of another embodiment of the electronic unit base of the present invention;

FIG. 10 is a top view of an embodiment of the present invention showing a plurality of electronic units disposed in parallel on the base;

FIG. 11A is a schematic view of an embodiment of the present invention showing a plurality of electronic units disposed in series on the base; and

FIG. 11B is a top view of an embodiment of the present invention showing a plurality of electronic units disposed in series on the base.

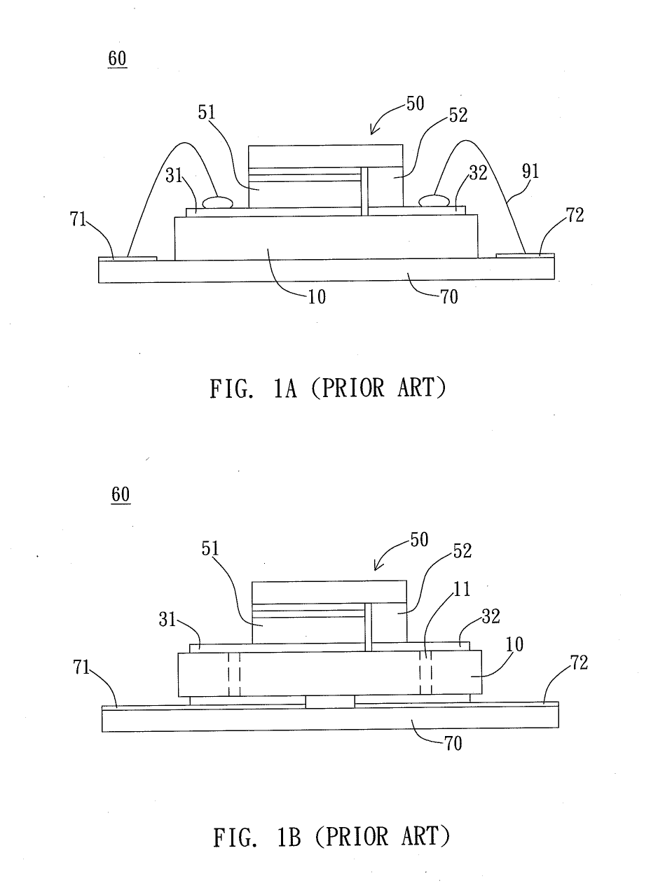

### DETAILED DESCRIPTION OF THE PREFERRED EMBODIMENT

The present invention provides an electronic unit base, and an electronic unit module and an electronic device using the same. The electronic unit is preferably a LED. The electronic unit base is preferably a Sub-Mount of a LED.

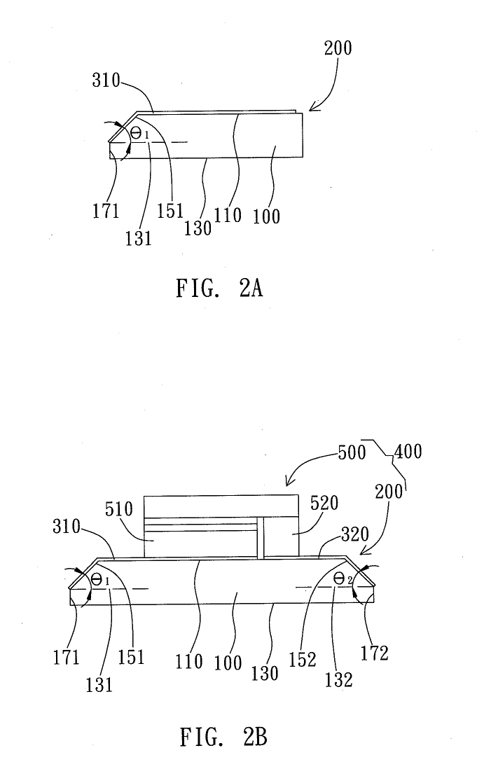

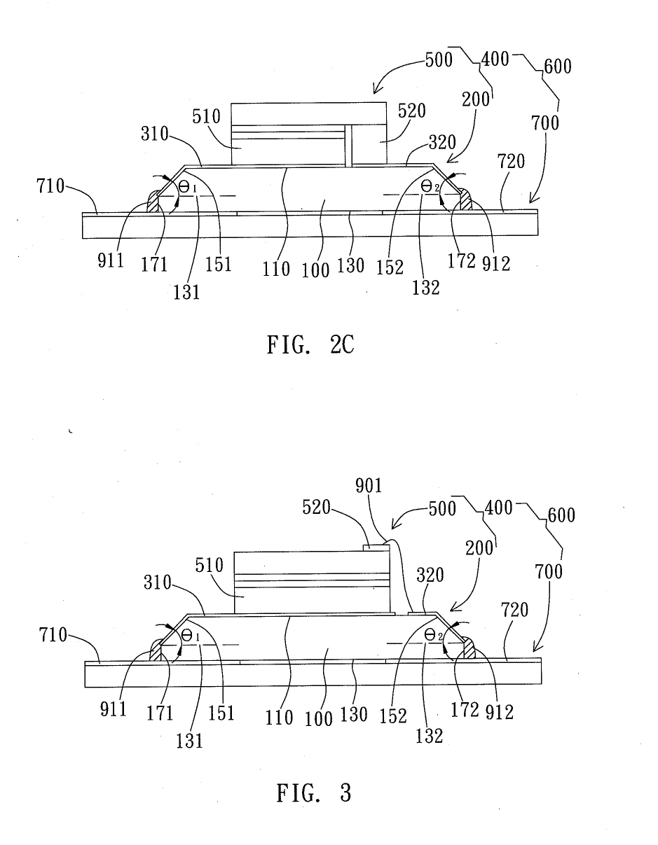

As the preferred embodiment shown in FIG. 2A, the electronic unit base 200 includes a body 100 and a first conducting layer 310. The body 100 includes a supporting face 110, a bottom face 130, and a first incline 151. The supporting face 110 and the bottom face 130 are disposed on opposite sides of the body 100. The first incline 151 is disposed on one side of the body 100 between the supporting face 110 and the bottom face 130, wherein the first incline 151 and the bottom face 130 substantially have a first angle θ₁. The first conducting layer 310 is disposed on the supporting face 110 and extends toward the first incline 151, wherein the first conducting layer 310 at least covers a portion of the supporting face 110 and a portion of the first incline 151. More particularly, the supporting face 110 and the bottom face 130 are respectively the top and the bottom of the body 100. The first incline 151 is the side of the body 100, wherein the first incline 151 and a parallel line 131 of the bottom face 130 have the first angle θ₁. The first angle θ₁ is preferably less than 90° and is more preferably between 30° and 85°. Since the first conducting layer 310 at least covers a portion of the supporting face 110 and a portion of the first incline 151, an electrode of an electronic unit on the electronic unit base 200 is coupled to the conducting material of the first incline 151 of the electronic unit base 200 more easily by the first conducting layer 310 when the electronic unit is disposed on the electrode unit base 200. The above advantage will be further described in the embodiment shown in FIG. 2C.

As the preferred embodiment shown in FIG. 2A, the electronic unit base 200 further includes a first side face 171 disposed between the first incline 151 and the bottom face 130. The height of the first side face 171 is preferably less than 1 mm. Taking a different point of view, there is a stage difference less than 1 mm between the bottom end of the first incline 151 and the bottom face 130. The first side face 171 connects the bottom end of the first incline 151 and the bottom face 130. The first side face 171 is preferably perpendicular to the bottom face 130. In a different embodiment, however, the first side face 171 and the bottom face 130 could have an angle other than right angle. Because of the stage difference between the bottom end of the first incline 151 and the bottom face 130, the bottom end of the first incline 151 can remain higher than the surface of a substrate when the bottom face 130 of the electronic unit base 200 is embedded into the substrate to a depth less than the stage difference. The above advantage will be further described in the embodiments shown in FIGS. 5-7.

As the preferred embodiment shown in FIG. 2B, the electronic unit module 400 of the present invention includes the above electronic unit base 200 and the electronic unit 500. In the preferred embodiment, the electronic unit base 200 further includes a second incline 152 and a second conducting layer 320. The second incline 152 is disposed on the other side of the body 100 between the supporting face 110 and the bottom face 130, wherein the second incline 152 and the bottom face 130 substantially have a second angle θ₂. The second conducting layer 320 is disposed on the supporting face 110 and extends toward the second incline 152, wherein the second conducting layer 320 covers a portion of the supporting face 110 and a portion of the second incline 152, and the second conducting layer 320 and the first conducting layer 310 are physically separated by, for example, a gap or an isolation object. The first incline 151 and the second incline 152 are preferably respectively disposed on opposite sides of the body 100 and between the supporting face 110 and the bottom face 130.

More particularly, in the preferred embodiment shown in FIG. 2B, the second incline 152 is the other side of the body 100 opposite to the first incline 151, wherein the second incline 152 and a parallel line 132 of the bottom face 130 have the second angle θ₂. The second angle θ₂ is preferably less than 90° and is more preferably between 30° and 85°. θ₂ is preferably equal to θ₁. In a different embodiment, however, θ₂ and θ₁ can be different for the benefit of manufacturing, using, or minimizing the size of the electronic unit base 200. The electronic unit base 200 further includes a second side face 172 disposed between the second incline 152 and the bottom face 130. The height of the second side face 172 is preferably less than 1 mm. Taking a different point of view, there is a stage difference less than 1 mm between the bottom end of the second incline 152 and the bottom face 130. The second side face 172 connects the bottom end of the second incline 152 and the bottom face 130. The second side face 172 is preferably perpendicular to the bottom face 130. In a different embodiment, however, the second side face 172 and the bottom face 130 could have an angle other than right angle.

As the preferred embodiment shown in FIG. 2B, the electronic unit 500 has a first electrode 510 and a second electrode 520 respectively coupled to the first conducting layer 310 and the second conducting layer 320 covering the supporting face 110. Because the first conducting layer 310 at least covers a portion of the supporting face 110 and a portion of the first incline 151, the second conducting layer 320 covers a portion of the supporting face 110 and a portion of the second incline 152, and the second conducting layer 320 and the first conducting layer 310 are physically separated, the two electrodes of the electronic unit 500 on the electronic unit base 200 are respectively coupled to the conducting materials of the first incline 151 and the second incline 152 of the electronic unit base 200 more easily by the first conducting layer 310 and the second conducting layer 320. The above advantage will be further described in the embodiment shown in FIG. 2C.

In the preferred embodiment shown in FIG. 2B, the electronic unit 500 is preferably a LED. More particularly, in the preferred embodiment, the electronic unit 500 is a Flip-Chip type LED. The first electrode 510 and the second electrode 520 are disposed on the same side of the electronic unit 500, wherein the first electrode 510 and the second electrode 520 are respectively coupled to the first conducting layer 310 and the second conducting layer 320 by Flip-Chip bonding of the electronic unit 500. However, the electronic unit is not limited to a Flip-Chip type LED. As a different embodiment shown in FIG. 3, the first electrode 510 and the second electrode 520 are disposed on opposite sides of the electronic unit 500, wherein the first electrode 510 covers and is coupled with the first conducting layer 310; the second electrode 520 is coupled to the second conducting layer 320 by a wire 901.

As the preferred embodiment shown in FIG. 2C, the electronic device 600 of the present invention includes the above electronic unit module 400 and a substrate 700. The substrate 700 has a first substrate electrode 710 and a second substrate electrode 720 respectively coupled to the first conducting layer 310 and the second conducting layer 320. In the preferred embodiment, the first substrate electrode 710 and the second substrate electrode 720 are respectively coupled to the first conducting layer 310 and the second conducting layer 320 by conducting pastes 911, 912. More particularly, when the electronic device is made, the electronic unit module 400 is disposed on the substrate 700 at a location for electrical connection. Then, the conducting paste 911 and 912 are respectively applied to the side of first incline 151 and the side of second incline 152 of the body 100. Accordingly, the first substrate electrode 710 and the second substrate electrode 720 are respectively coupled to the first conducting layer 310 and the second conducting layer 320

In general, the conducting pastes 911, 912 are fluidable liquid or semi-solid that could be solidified with the lapse of time or under certain conditions such as light exposing or heating. Since the first incline 151 and the bottom face 130 substantially have a first angle θ₁, and the second incline 152 and the bottom face 130 substantially have a second angle θ₂, i.e. both the first incline 151 and the second incline 152 are inclined with respect to the substrate 700, instead of perpendicular to the substrate 700, it is advantageous to apply and cover the conducting paste 911 and 912 on at least a portion of the first conducting layer 310 on the first incline 151 and the second conducting layer 320 on the second incline 152 as well as the first substrate electrode 710 and the second substrate electrode 720. As a result, the success rate and stability of respectively coupling the first substrate electrode 710 and the second substrate electrode 720 to the first conducting layer 310 and the second conducting layer 320 by conducting pastes 911, 912 are promoted. In other words, with the first incline 151 and the second incline 152, coupling the first substrate electrode 710 and the second substrate electrode 720 to the first conducting layer 310 and the second conducting layer 320 by conducting pastes 911, 912 can be achieved. Accordingly, neither connection of wire nor formation of holes in the body of the Sub-Mount is required. A wireless packaging can be achieved at lower cost. On the other hand, as the embodiment shown in FIG. 3, even if the wire 901 is employed because the first electrode and the second electrode are disposed on opposite sides of the electronic unit, the possibility of breaking the wire 901 can be reduced since the wire 901 has a shorter coupling length from the second electrode 520 to the second conducting layer 320, instead of to a substrate electrode.

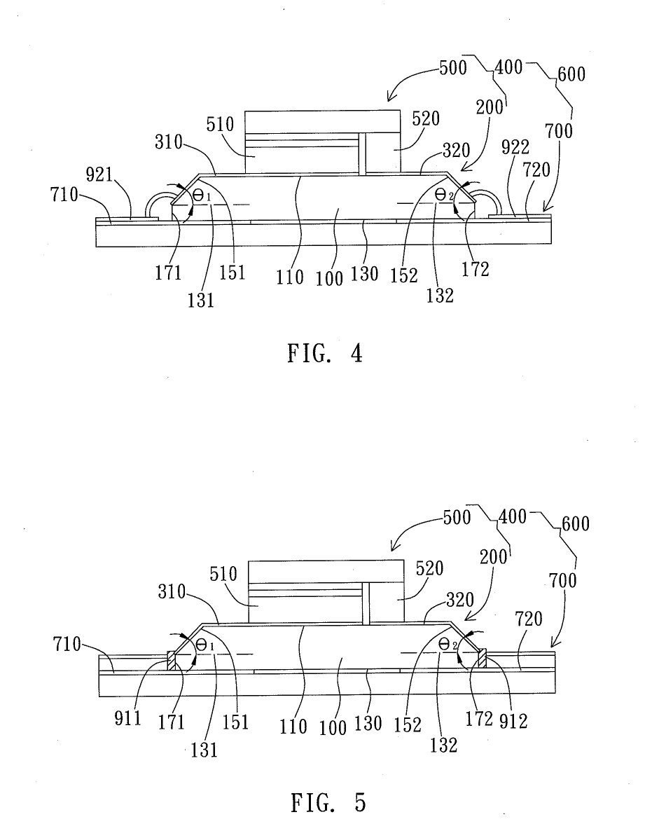

In different embodiments, it is not limited that the first substrate electrode 710 and the second substrate electrode 720 are respectively coupled to the first conducting layer 310 and the second conducting layer 320 by conducting paste. As a different embodiment shown in FIG. 4, the first substrate electrode 710 and the second substrate electrode 720 respectively have a first reed 921 and a second reed 922, wherein the first substrate electrode 710 and the second substrate electrode 720 are respectively coupled to the first conducting layer 310 and the second conducting layer 320 by using the first reed 921 and the second reed 922. More particularly, the first reed 921 and the second reed 922 are disposed on the substrate 700 in advance and respectively coupled to the first substrate electrode 710 and the second substrate electrode 720. When the electronic device is made, the electronic unit module 400 is inserted into the position between the first reed 921 and the second reed 922 on the substrate 700. As a result, the free ends of the first reed 921 and the second reed 922 are able to respectively contact the first conducting layer 310 and the second conducting layer 320, and respectively make the first conducting layer 310 and the second conducting layer 320 couple to the first substrate electrode 710 and the second substrate electrode 720. Since the first incline 151 and the bottom face 130 substantially have a first angle θ₁, and the second incline 152 and the bottom face 130 substantially have a second angle θ₂, i.e. both the first incline 151 and the second incline 152 are inclined with respect to the substrate 700, instead of perpendicular to the substrate 700, it is advantageous to make the free ends of the first reed 921 and the second reed 922 respectively contact the first conducting layer 310 and the second conducting layer 320. As a result, the success rate and stability of respectively coupling the first substrate electrode 710 and the second substrate electrode 720 to the first conducting layer 310 and the second conducting layer 320 by the first reed 921 and the second reed 922 are promoted.

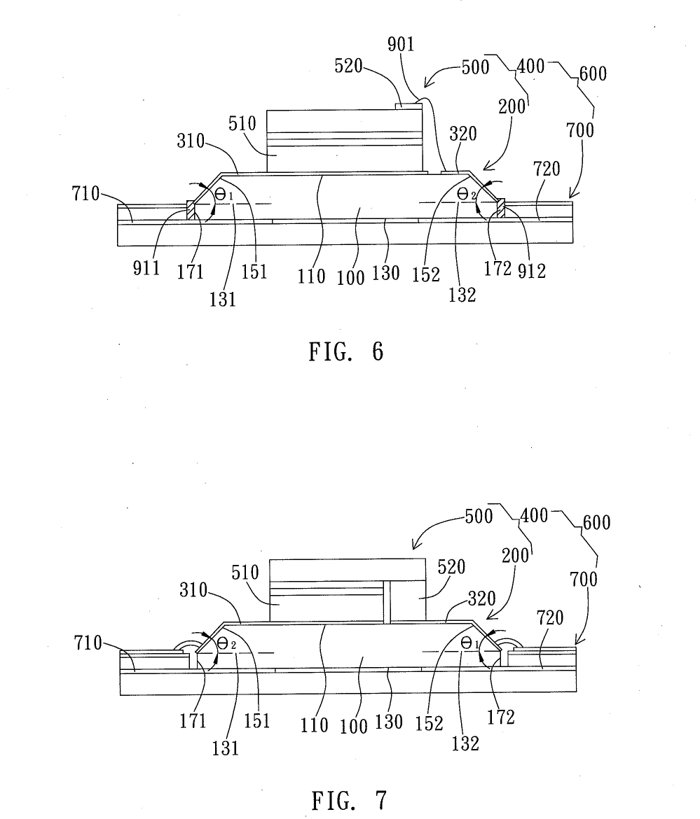

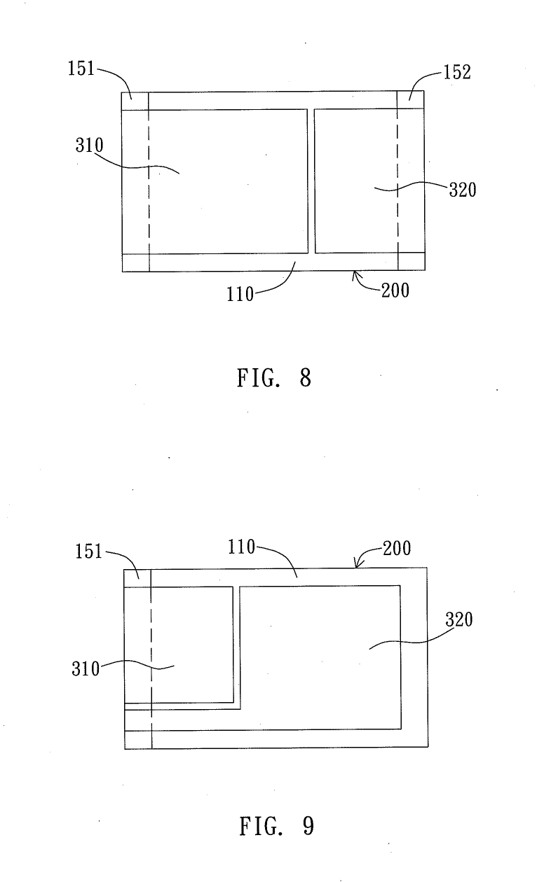

As different embodiments shown in FIGS. 5-7, the electronic device 600 of the present invention can be an embedding-type, which means the electronic unit module 400 is embedded into the substrate 700, wherein the bottom face 130 of the electronic unit base 200 is sunk into the substrate 700. More particularly, the electronic unit module 400 is preferably embedded into the substrate 700, wherein at least a portion of the first side face 171 is sunk into the substrate 700, and at least a portion of the second side face 172 is sunk into the substrate 700. As shown in FIGS. 5-6, the electronic unit module 400 is more firmly disposed on the substrate 700 since it is embedded into the substrate 700. Because of the stage difference between the bottom end of the first incline 151 and the bottom face 130, and between the bottom end of the second incline 151 and the bottom face 130, the bottom ends of the first incline 151 and the second incline 152 can remain higher than the surface of a substrate 700 when the bottom face 130 of the electronic unit base 200 is embedded into the substrate 700 to a depth less than the stage difference. In other words, the first conducting layer 310 and the second conducting layer 320 remain higher than the surface of the substrate 700 to make it more easily to respectively couple the first conducting layer 310 and the second conducting layer 320 to the first substrate electrode 710 and the second substrate electrode 720. On the other hand, when the first substrate electrode 710 and the second substrate electrode 720 are respectively coupled to the first conducting layer 310 and the second conducting layer 320 by conducting pastes 911 and 912, the amount of conducting pastes 911 and 912 can be reduced at a cost effective manner since the stage difference between the first conducting layer 310 and the first substrate electrode 710 as well as the stage difference between the second conducting layer 320 and the second substrate electrode 720 are decreased. Moreover, conducting pastes 911 and 912 can further be filled into the gaps between the first side face 171 and the substrate 700 as well as between the second side face 172 and the substrate 700 to make the electronic unit module 400 more tightly embedded into the substrate 700.

As shown in FIG. 7, the first substrate electrode 710 and the second substrate electrode 720 are respectively coupled to the first conducting layer 310 and the second conducting layer 320 by using the first reed 921 and the second reed 922. In general, as the reed has a greater deformation, the cost will be higher and the elasticity is more easily decreased for a long time operation. With the design Shown in FIG. 7, when the first substrate electrode 710 and the second substrate electrode 720 are respectively coupled to the first conducting layer 310 and the second conducting layer 320 by the first reed 921 and the second reed 922, the deformation of the first reed 921 and the second reed 922 can be reduced to increase their weariness-resistance since the stage difference between the first conducting layer 310 and the first substrate electrode 710 as well as the stage difference between the second conducting layer 320 and the second substrate electrode 720 are decreased.

In the embodiments shown in FIGS. 2B-7, the electronic unit base 200 has the first incline 151 and the second incline 152 respectively for the first conducting layer 310 and the second conducting layer 320 to extend thereto. In different embodiments, however, the first conducting layer 310 and the second conducting layer can be disposed and extend toward the same incline. More particularly, as a different embodiment shown in FIG. 9, the electronic unit base 200 includes a first conducting layer 310 and a second conducting layer 320 that are both disposed on the supporting face 110 and extend toward the first incline 151, and covers a portion of the supporting face 110 and a portion of the first incline 151. The second conducting layer 320 and the first conducting layer 310 are physically separated. With this design, even if the electronic unit base 200 only has one incline, i.e. the first incline 151, two conducting layers can still be disposed for the first electrode 510 and the second electrode 520 of the electronic unit 500 described in FIGS. 2B-7 to couple thereto.

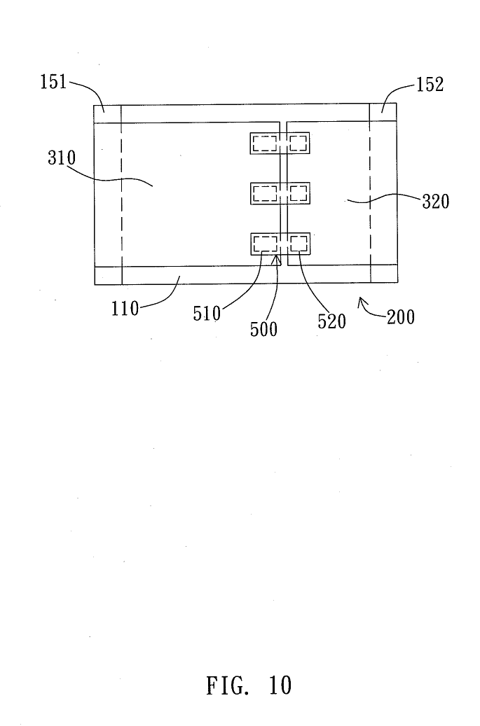

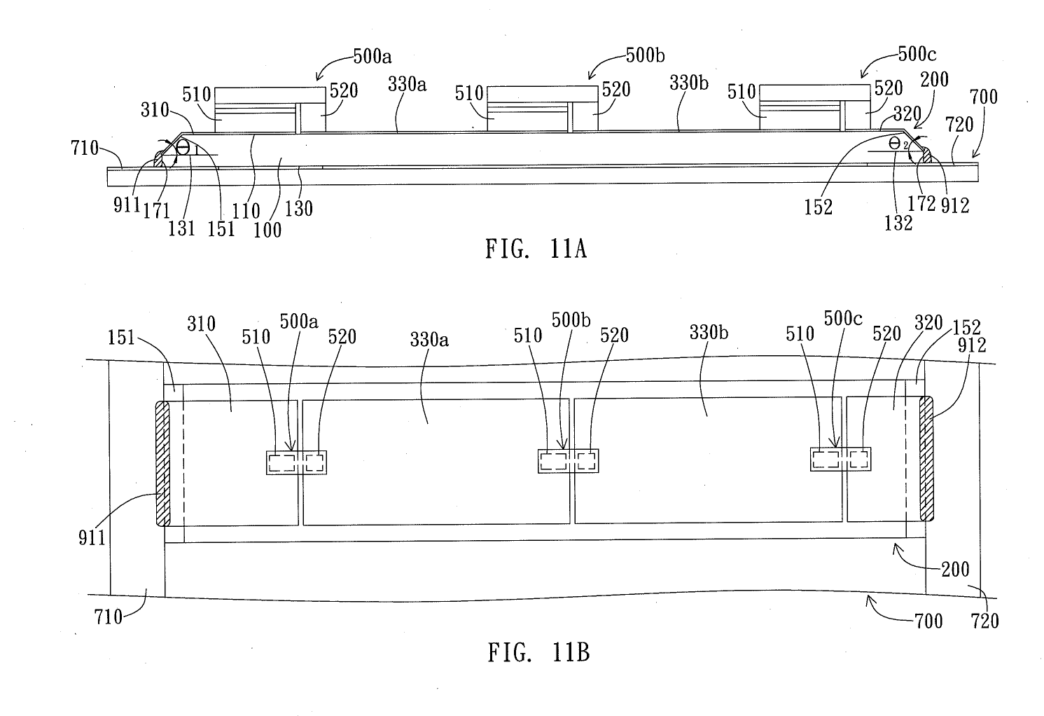

In different embodiments, a plurality of electronic units can be disposed in series or in parallel on the electronic unit base 200. More particularly, as the embodiment shown in FIG. 10, the plurality of electronic units 500 are disposed in parallel on the electronic unit base 200. The first electrode 510 of each electronic unit 500 is coupled to the first conducting layer 310. The second electrode 520 of each electronic unit 500 is coupled to the second conducting layer 320. As the embodiments shown in FIGS. 11A and 11B, the electronic unit base 200 further includes conducting electrodes 330a and 330b disposed on the supporting face 110. The electronic unit module 400 includes the electronic unit base 200 and the electronic units 500a, 500b, and 500c. The electronic units 500a, 500b, and 500c each has a first electrode 510 and a second electrode. The first electrode 510 is coupled to the first conducting layer 310 covering the supporting face 110. The second electrode 520 of the electronic unit 500c is coupled to the second conducting layer 320 covering the supporting face 110. The electronic units 500a, 500b, and 500c are coupled to each other in series by the conducting electrodes 330a and 330b. The electronic device 600 includes the electronic unit module 400 and the substrate 700 having the first substrate electrode 710 and the second substrate electrode 720 respectively coupled to the first conducting layer 310 and the second conducting layer 320. More particularly, by coupling the electronic units in series or in parallel, a plurality of electronic units can share one electronic unit base and one substrate to decrease the cost and increase the flexibility of design.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

1. An electronic unit base, comprising:
a body including a supporting face, a bottom face, and a first incline, wherein the supporting face and the bottom face are disposed on opposite sides of the body, wherein the first incline is disposed on one side of the body between the supporting face and the bottom face, wherein the first incline and the bottom face substantially have a first angle; and
a first conducting layer disposed on the supporting face and extending toward the first incline, wherein the first conducting layer covers a portion of the supporting face and a portion of the first incline.

2. The electronic unit base of claim 1, further comprising a first side face disposed between the first incline and the bottom face.

3. The electronic unit base of claim 1, wherein the height of the first side face is less than 1 mm.

4. The electronic unit base of claim 1, further comprising:
a second incline disposed on the other side of the body between the supporting face and the bottom face, wherein the second incline and the bottom face substantially have a second angle; and
a second conducting layer disposed on the supporting face and extending toward the second incline, wherein the second conducting layer covers a portion of the supporting face and a portion of the second incline, wherein the second conducting layer and the first conducting layer are physically separated.

5. The electronic unit base of claim 4, wherein the first incline and the second incline are respectively disposed on opposite sides of the body and between the supporting face and the bottom face.

6. The electronic unit base of claim 4, further comprising a second side face disposed between the second incline and the bottom face.

7. The electronic unit base of claim 6, wherein the height of the second side face is less than 1 mm.

8. The electronic unit base of claim 1, further comprising a second conducting layer disposed on the supporting face and extending toward the first incline, wherein the second conducting layer covers a portion of the supporting face and a portion of the first incline, wherein the second conducting layer and the first conducting layer are physically separated.

9. A electronic unit module, comprising:
the electronic unit base of claim 4; and
an electronic unit having a first electrode and a second electrode respectively coupled to the first conducting layer and the second conducting layer coving the supporting face.

10. The electronic unit module of claim 9, wherein the electronic unit is a LED.

11. The electronic unit module of claim 9, wherein the first electrode and the second electrode are disposed on the same side of the electronic unit, wherein the first electrode and the second electrode are respectively coupled to the first conducting layer and the second conducting layer by Flip-Chip bonding of the electronic unit.

12. The electronic unit module of claim 9, wherein the first electrode and the second electrode are disposed on opposite sides of the electronic unit, wherein the first electrode covers and is coupled with the first conducting layer, wherein the second electrode is coupled to the second conducting layer by a wire.

13. An electronic device, comprising:
the electronic unit module of claim 9; and
a substrate having a first substrate electrode and a second substrate electrode respectively coupled to the first conducting layer and the second conducting layer.

14. The electronic device of claim 13, wherein the first substrate electrode and the second substrate electrode are respectively coupled to the first conducting layer and the second conducting layer by conducting paste.

15. The electronic device of claim 13, wherein the first substrate electrode and the second substrate electrode respectively have a first reed and a second reed, wherein the first substrate electrode and the second substrate electrode are respectively coupled to the first conducting layer and the second conducting layer by using the first reed and the second reed.

16. The electronic device of claim 13, wherein the electronic unit module is embedded into the substrate, the bottom face is sunk into the substrate.

17. The electronic device of claim 13, wherein the electronic unit module is embedded into the substrate, at least a portion of the first side face is sunk into the substrate.

18. The electronic unit base of claim 4, further comprising at least one conducting electrode disposed on the supporting face.

19. The electronic unit base of claim 18, further comprising a plurality of electronic units, wherein each electronic unit has a first electrode and a second electrode, wherein the first electrode of one of the plurality of electronic units is coupled to the first conducting layer covering the supporting face and the second electrode of another of the plurality of electronic units is coupled to the second conducting layer covering the supporting face, wherein the plurality of electronic units are coupled to each other in series by the at least one conducting electrode.

20. The electronic unit base of claim 19, further comprising a substrate that having a first substrate electrode and a second substrate electrode respectively coupled to the first conducting layer and the second conducting layer.
